(19) United States
(12) Patent Application Publication
(10) Pub. No.: US 2026/0165043 A1
(43) Pub. Date: Jun. 11, 2026

(54) AREA SELECTIVE CARBON PARTIAL GAPFILL PROCESS

(71) Applicant: Applied Materials, Inc., Santa Clara, CA (US)

(72) Inventors: Peiqi WANG, Campbell, CA (US); Anantha Venkataraman NAGARAJAN, Sunnyvale, CA (US); Vamshi Krishna GADDAMEDI, Sunnyvale, CA (US); Abdul Aziz KHAJA, San Jose, CA (US)

(21) Appl. No.: 19/180,334

(22) Filed: Apr. 16, 2025

Related U.S. Application Data
(60) Provisional application No. 63/634,881, filed on Apr. 16, 2024.

(51) Int. Cl. H10P 14/60; C23C 16/04; C23C 16/26; H10P 14/69

(52) U.S. Cl. CPC H10P 14/6336; C23C 16/045; C23C 16/26; H10P 14/6902

(57) ABSTRACT

A method includes receiving a substrate in a process volume, the substrate comprising structures thereon having varying critical dimensions. A plasma is formed in a process volume. A top surface of the structures is chemically modified with an inert termination group using the plasma. Subsequent to modifying the top surface of the structures, a dielectric film is deposited over a surface of the substrate. The dielectric film is deposited in a trench between adjacent structures.

### CROSS-REFERENCE TO RELATED APPLICATIONS

This application claims benefit of United States provisional patent application Ser. No. 63/634,881, filed Apr. 16, 2024, which is herein incorporated by reference.

### BACKGROUND

### Field

Embodiments of the present disclosure generally relate to manufacture of semiconductor components and devices. More specifically, embodiments described herein provide methods for the selective deposition of carbon in a gapfill process.

### Description of the Related Art

In semiconductor processing, devices are being manufactured with continually decreasing feature dimensions. Often, features utilized to manufacture devices at these advanced technology nodes include high aspect ratio structures, and it is often necessary to fill gaps between circuit elements/structures with a variety of materials. Examples where gapfill material layers are utilized include filling shallow trench isolation (STI), horizontal interconnects, vias between adjacent metal layers, inter-metal dielectric layers (ILD), pre-metal dielectrics (PMD), passivation layers, patterning applications, etc. As the width between the structures shrink, the gap between them often gets taller and narrower, making the gap more difficult to fill without the gapfill material being stuck on sidewalls and creating voids and weak seams. Furthermore, oftentimes a single device or substrate will have multiple gaps of varying widths (e.g., critical dimensions (CD)) and/or aspect ratios that will need to be filled with the gapfill material.

Conventional spin on carbon (SOC) gapfill or chemical vapor deposition (CVD) techniques often experience an overgrowth of material at the top of the gap before it has been completely filled. This can create a void or seam in the gap where the depositing material has been prematurely cut off by the overgrowth; a problem sometimes referred to as bread-loafing. As device geometries shrink and thermal budgets are reduced, void-free and seam-free filling of high aspect ratio spaces becomes increasingly difficult due to limitations of existing deposition processes, especially for forming gapfill material layers to concurrently fill multiple gaps with different CDs and/or aspect ratios. Other problems associated with SOC include peeling when exposed to wet chemistries. By protecting the bottom of trench with PECVD carbon while doing post processing with dry and wet etch chemistries provides solutions to these problems.

Conventional PECVD gapfill processes have pattern loading issues due to various pattern densities and CDs. Conventional PECVD gapfill processes suffer from formation of ‘top hats’ where more material is deposited in the middle region than sidewall regions due to shadow effects, resulting in triangular growth. Meanwhile, state of the art spin on carbon (SOC) requires multiple operations of SOC, plus treatments, plus etches, to address variable CD/AR hampering throughput significantly. Therefore, improved techniques are needed for selectively depositing carbon films, particularly for logic and DRAM applications.

### SUMMARY

In one embodiment, a method for depositing a dielectric film is disclosed. The method includes receiving a substrate in a process volume, the substrate including structures thereon having varying critical dimensions. A plasma is formed in a process volume. A top surface of the structures is chemically modified with an inert termination group using the plasma. Subsequent to modifying the top surface of the structures, a dielectric film is deposited over a surface of the substrate. The dielectric film is deposited in a trench between adjacent structures.

In another embodiment, a method for depositing a dielectric film is disclosed. The method includes receiving a substrate in a process volume. The substrate includes structures thereon having varying critical dimensions and defining a plurality of trenches. A first layer is disposed over the substrate in the trenches and a second layer is disposed over the first layer in the trenches and over a top surface of the structures. A dielectric film is disposed over the substrate. The dielectric film is etched to expose the second layer disposed over the top surface of the structures. The second layer exposed by the dielectric film is etched to remove the second layer from the top surface of the structures.

In yet another embodiment, a device is disclosed. The device includes a substrate including a plurality of structures. The plurality of structures define a plurality of trenches. A dielectric film is disposed in the trenches. The dielectric film includes a carbon-containing material.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, and may admit to other equally effective embodiments.

FIG. 1 is a schematic cross-sectional view of a process chamber, according to certain embodiments.

FIG. 2 is a diagram of a method for forming a carbon gapfill via suppressed nucleation, according to embodiments.

FIG. 3A-3C are schematic cross-sectional view of a substrate during the method of FIG. 2, according to embodiments.

FIG. 4 is a diagram of a method for forming a carbon gapfill via a full-fill etch back, according to embodiments.

FIG. 5A-5D are schematic cross-sectional view of a substrate during the method of FIG. 4, according to embodiments.

FIG. 6 is a flow diagram of a second method for forming a carbon gapfill via a full-fill etch back, according to embodiments.

FIGS. 7A-7D are schematic cross-sectional views of a substrate during the method of FIG. 6, according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to manufacture of semiconductor components and devices. More specifically, embodiments described herein provide methods for the selective deposition of carbon in a gapfill process.

Many of the details, dimensions, angles and other features shown in the figures are merely illustrative of particular embodiments. Accordingly, other embodiments can have other details, components, dimensions, angles and features without departing from the spirit or scope of the present disclosure. In addition, further embodiments of the disclosure can be practiced without several of the details described below.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals (e.g., tungsten), metal nitrides (e.g., TiN), metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface.

In addition to film processing directly on the surface of the substrate itself, in the present disclosure, any of the processing steps disclosed may also be performed on an intermediate layer formed on the substrate as disclosed in more detail below, and the term “substrate surface” is intended to include such intermediate layer as the context indicates. Thus, for example, where a film/layer or partial film/layer has been deposited onto a substrate surface, the exposed surface of the newly deposited film/layer becomes the substrate surface.

Carbon-based film deposition has been used to provide gapfill material layers during semiconductor processing through vapor deposition process techniques, such as CVD or plasma enhanced chemical vapor deposition (PECVD). Most vapor deposition methods, including CVD and PECVD, utilize a blanket deposition process that generally deposits more gapfill material along a top surface of a feature, where a trench between the features remains void of the gapfill material layer.

Embodiments of the present disclosure provide techniques for performing a deposition with the use a high frequency radio frequency (HFRF), e.g., about 13.56 MHz to about 50 MHz, to form a carbon gapfill layer in a trench between adjacent vertical structures having varying critical dimensions, e.g., critical dimensions from about 8 nm to about 1000 nm, e.g., about 8 nm to about 800 nm, about 100 nm to about 600 nm, about 200 nm to about 400 nm, or about 250 nm to about 350 nm, about 8 nm to about 50 nm, about 50 nm to about 100 nm, about 100 nm to about 150 nm, about 150 nm to about 200 nm, about 200 nm to about 250 nm, about 250 nm to about 500 nm, or about 500 nm to about 1000 nm. Without being bound by theory, the growth profile of the carbon gapfill layer in each of the trenches may be more uniform when using HFRF as compared to conventional carbon gapfill processes.

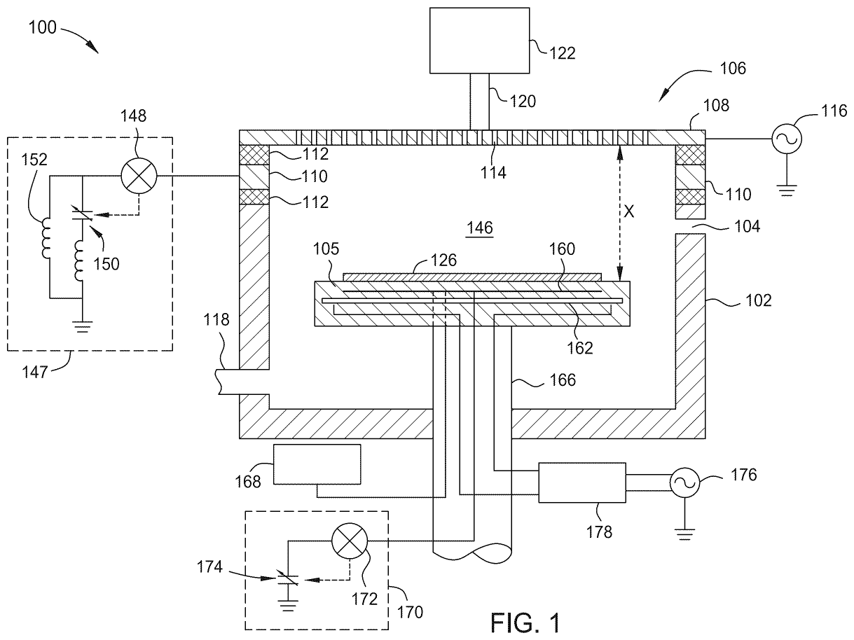

FIG. 1 is a schematic cross sectional view of a process chamber 100 configured according to various embodiments of the present disclosure. By way of example, the embodiment of the process chamber 100 in FIG. 1 is described in terms of a PECVD system, but any other process chamber may fall within the scope of the embodiments, including other plasma deposition chambers or plasma etch chambers. The process chamber 100 includes a chamber body 102, a lid assembly 106, and a substrate support 105. The lid assembly 106 is disposed at an upper end of and is supported by the chamber body 102, and the substrate support 105 is at least partially disposed within the chamber body 102. The chamber body 102, lid assembly 106, and substrate support 105 together define a processing volume 146 within the process chamber 100 in which a substrate 126 may be processed. The processing volume 146 may be accessed through a port 104 formed in the chamber body 102 that facilitates transfer of a substrate into and out of the processing volume 146 of the process chamber 100.

The lid assembly 106 includes a gas distributor 108, a modulation electrode 110, and insulators 112. In some embodiments, the modulation electrode 110 is optional. The insulator 112, which may be a dielectric material such as a ceramic or metal oxide, for example aluminum oxide and/or aluminum nitride. The insulator 112 contacts the modulation electrode 110 and separates the modulation electrode 110 electrically and thermally from the gas distributor 108 and from the chamber body 102. The gas distributor 108 (e.g., showerhead) has passages 114 therethrough for admitting process gas into the processing volume 146. A pair of insulators (e.g., annular insulators) are disposed between the gas distributor 108 and the modulation electrode 110. The modulation electrode 110 is annular and circumscribes the processing volume 146.

Process gases (e.g., one or more precursor and one or more inert carrier gas) may be provided through the conduit 120 from a gas source 122 to be introduced into the process chamber 100. The processing gas from the conduit 120 enters the processing volume 146 through the passages 114 in the gas distributor 108 such that the processing gas is uniformly distributed in the processing volume 146. In one embodiment, the passages 114 in the gas distributor 108 may be radially distributed and gas flow to each of the passages 114 may be separately controlled to further facilitate gas uniformity within the processing volume 146.

The processing gases can be evacuated from the processing volume 146 through an outlet 118 which may be located at any convenient location along the chamber body 102. In some embodiments, the outlet 118 may be associated with a vacuum pump (not shown) fluidly coupled to the processing volume 146. The vacuum pump may be part of the gas and pressure control system of the processing chamber 100.

In some embodiments, portions of the gas distributor 108 may be heated using a resistive heater (not shown) or thermal fluid disposed in a conduit (not shown) through a portion of the gas distributor 108 or otherwise in direct contact or thermal contact with the gas distributor 108. The conduit may be disposed through an edge portion of the gas distributor 108 to avoid disturbing the gas flow function of the gas distributor 108. Heating the edge portion of the gas distributor 108 may be useful to reduce the tendency of the edge portion of the gas distributor 108 to be a heatsink within the process chamber 100.

In some embodiments, the walls of the chamber body 102 may also be heated to similar effect. Heating the chamber surfaces exposed to the plasma also minimizes deposition, condensation, and/or reverse sublimation on the chamber surfaces, reducing the cleaning frequency of the chamber and increasing mean cycles per clean. Higher temperature surfaces also promote dense deposition that is less likely to produce particles that fall onto a substrate. Thermal control conduits with resistive heaters and/or thermal fluids (not shown) may be disposed through the chamber walls to achieve thermal control of the chamber walls. Temperature of all surfaces may be controlled by a controller.

In some embodiments, the gas distributor 108 may be coupled to a RF power source 116, such as a RF generator, as shown in FIG. 1. DC power, pulsed DC power, and pulsed RF power source may alternatively be used. In other embodiments, the gas distributor 108 may be coupled to ground. The RF power source 116 is electrically connected to the gas distributor 108 and is configured to apply a RF potential to the gas distributor 108 to facilitate the generation of plasma in the interior processing volume 146. In some embodiments, the RF power source 116 may be a high frequency RF power source (“HFRF power source”) capable of generating an HFRF power (e.g., at a frequency of about 10 MHz to about 40 MHz, e.g., about 20 MHz to about 22 MHz, about 22 MHz to about 24 MHz, about 24 MHz to about 26 MHz, about 26 MHz to about 28 MHz, about 28 MHz to about 30 MHz, about 30 MHz to about 50 MHz, or about 35 MHz to about 45 MHz). The HFRF power source can be designed for use with a fixed match and can regulate the power delivered to the load, eliminating concerns about forward and reflected power. Without being bound by theory, an HFRF power source can provide an increase in the C₂H production rate and H production rate when using C₂H₂ as a process gas, thereby producing a more conformal and/or uniform carbon gapfill in trenches between one or more features, and reducing pattern loading effects. The HFRF power enables increased radical flux during generation of the plasma in the interior processing volume 146, while also enabling a decrease in the pressure in the processing volume. An overall increase in power enables an overall increase in flux. An increase in the power and an increase in pressure enables in an increase in radical flux.

In other embodiments, the RF power source 116 may be a low frequency RF power source (“LFRF power source”) capable of generating an LFRF power (e.g., at a frequency of about 300 kHz to about 3 MHz, such as about 350 kHz to about 2 MHz). The LFRF power source can provide both low frequency generation and fixed match elements. The LFRF, in combination with higher pressure, is an ion driven process that enables increased radical flux during the generation of the plasma in the interior processing volume 146.

In further embodiments, an additional power source (not shown) may be added with the RF power source 116 to provide a dual RF power source to the process chamber 100. The modulation electrode 110 may be coupled to a tuning circuit 147 that controls an impedance of an electrical path from the modulation electrode 110 to an electrical ground. The tuning circuit 147 comprises an electronic sensor 148 and an electronic controller, which may be a variable capacitor 150 as shown that is controllable by the electronic sensor 148. The tuning circuit 147 may be an LLC circuit comprising one or more inductors 152. The electronic sensor 148 may be a voltage or current sensor and may be coupled to the variable capacitor 150 to afford a degree of closed-loop control of plasma conditions inside the processing volume 146. In some embodiments, the tuning circuit 147 may be any circuit that features a variable or controllable impedance under the plasma conditions present in the processing volume 146 during processing

The substrate support 105 may be disposed within the process chamber 100. The substrate support 105 may support the substrate 126 during processing. A first electrode 160 and a second electrode 162 are disposed in and/or on the substrate support 105. Further, in some embodiments, a heater element (not shown) may be embedded in the substrate support 105. The heater element can be operable to controllably heat the substrate support 105 and the substrate 126 positioned thereon to a target temperature, such as to maintain the substrate 126 at a temperature in a range from about 350 degrees Celsius to about 500 degrees Celsius.

The substrate support 105 is coupled to a shaft 166 for support. The shaft 166 can provide a conduit from a gas source 168 and electrical and temperature monitoring leads (not shown) between the substrate support 105 and other components of the process chamber 100. In some examples, a purge gas may be provided from the gas source 168 to the backside of the substrate 126 through one or more purge gas inlets connected to the substrate support 105. The purge gas flowed toward the backside of the substrate 126 can help prevent particle contamination caused by deposition on the backside of the substrate 126. The purge gas may also be used as a form of temperature control to cool the backside of the substrate 126. Although not illustrated, the shaft 166 may be coupled to an actuator (not shown) which extends through a centrally-located opening formed in a bottom of the chamber body 102. The actuator may be flexibly sealed to the chamber body 102 by bellows (not shown) that prevent vacuum leakage from around the shaft 166. The actuator can allow the substrate support 105 to be moved vertically within the chamber body 102 between a process position and a lower, transfer position. The transfer position is slightly below the port 104 in the chamber body 102. In operation, the substrate support 105 may be elevated to a position in close proximity to the lid assembly 106 for processing.

The first electrode 160 may be embedded within the substrate support 105 or coupled to a surface of the substrate support 105. The first electrode 160 may be a plate, a perforated plate, a mesh, a wire screen, or any other distributed arrangement. The first electrode 160 may be a tuning electrode and may be coupled to a tuning circuit 170. The tuning circuit 170 may have an electronic sensor 172 and an electronic controller, such as a variable capacitor 174 electrically connected between the first electrode 160 and an electrical ground. The electronic sensor 172 may be a voltage or current sensor and may be coupled to the variable capacitor 174 to provide further control over plasma conditions in the processing volume 146.

The second electrode 162, which may be a bias electrode and/or an electrostatic chucking electrode, may be coupled to the substrate support 105. The second electrode 162 may be coupled to a bias power source 176 through an impedance matching circuit 178. The bias power source 176 may be DC power, pulsed DC power, RF power, pulsed RF power, or a combination thereof (e.g., pulsing HFRF or continuous wave HFRF).

In operation, the substrate 126 is disposed on the substrate support 105, and process gases are flowed through the lid assembly 106 according to any desired flow plan. Electric power is coupled to the gas distributor to establish a plasma in the processing volume 146. The substrate 126 may be subjected to an electrical bias using the bias power source 176, if desired.

Upon energizing a plasma in the processing volume 146, a potential difference is established between the plasma and the modulation electrode 110. A potential difference is also established between the plasma and the first electrode 160. The variable capacitors 150 and 174 may then be used to adjust the impedances of the paths to an electrical ground represented by the tuning circuits 147 and 170. A set point may be delivered to the tuning circuit 147 and 170 to provide independent control of the plasma density uniformity from center to edge and deposition rate. The electronic sensors may adjust the variable capacitors to maximize deposition rate and minimize thickness non-uniformity independently. The components implemented to control temperature and uniformity of the plasma, among other, can permit deposition of a highly conformal layer on a substrate being processed, even within small gaps.

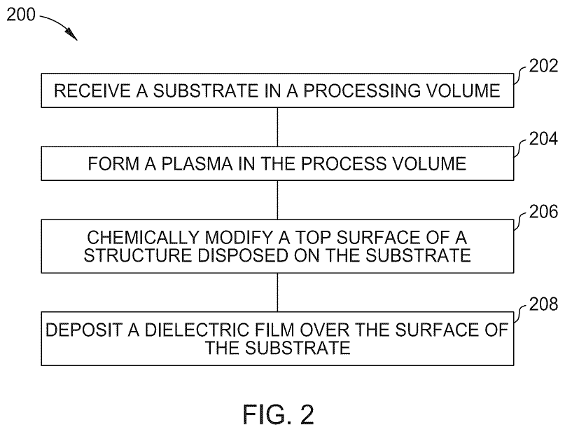

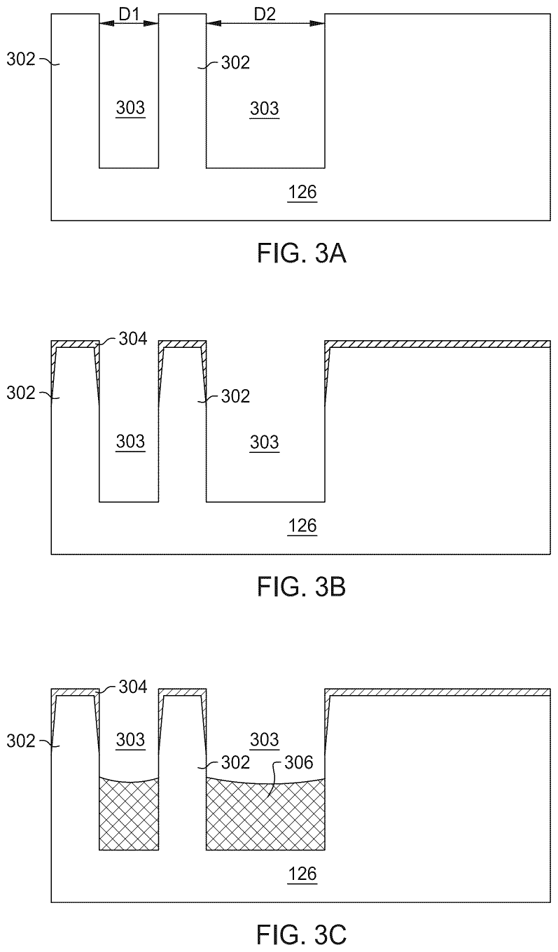

FIG. 2 is a diagram of a method 200 for forming a carbon gapfill via suppressed nucleation. FIG. 3A-3C are schematic cross-sectional view of a substrate during the method 200, according to embodiments. During the method 200, the substrate 126 is maintained at a temperature of about 300° C. to about 500° C., such as about 350° C. to about 450° C. During the method 200, the power supplied to the process chamber 100 is a high frequency (HF) power. The HF power is from about 500 W to about 3000 W, such as about 1000 W to about 2500 W, such as about 1500 W to about 2000 W.

At operation 202, a substrate 126 is received in a process volume 146. The substrate 126, as shown in FIG. 3A, includes structures 302 disposed thereon. The structures 302 define a plurality of trenches 303 in between the structures 302. The structure 302 have varying critical dimensions (CD), e.g., critical dimensions from about 8 nm to about 1000 nm, e.g., about 8 nm to about 800 nm, about 100 nm to about 600 nm, about 200 nm to about 400 nm, or about 250 nm to about 350 nm, about 8 nm to about 50 nm, about 50 nm to about 100 nm, about 100 nm to about 150 nm, about 150 nm to about 200 nm, about 200 nm to about 250 nm, about 250 nm to about 500 nm, or about 500 nm to about 1000 nm. For example, a first critical dimension D1 may be from 3 nm to about 100 nm, while a second critical dimension D2 is from about 150 nm to 400 nm. In some embodiments, the structure 302 is a wide structure, e.g., has a CD of 500 nm to 40 μm.

At operation 204, forming a plasma in the process volume 146. A process gas is supplied to the process volume 146 from the gas distributor 108 and/or the gas source 168. The plasma may be formed from th process gas. The process gas includes H₂, NH₃, N₂O, CO₂, other suitable process gases, or combinations thereof. The chemistry of the plasma is generally in the form of a plasma with a predetermined ion/radical ratio, from about 1:1 to about 1:50, such as about 1:5 to about 1:40, such as about 1:10 to about 1:30.

At operation 206, as shown in FIG. 3B, a top surface of the structures 302 is chemically modified. The top surfaces of the structures 302 are chemically modified to form an inert termination group 304 using the plasma. In some embodiments, the inert termination groups are formed using Si—H termination, and prevent the hot phosphorous etching. The Si—H termination is performed using argon and hydrogen treatments. In other embodiments, the inert termination groups are formed using N—H termination. The N—H termination is performed using nitrogen and hydrogen to promote the hot phosphorous etching. The combination of the chemistry as well as the ion/radical ratio facilitates differentiation of various surface modifications. During operation 206, the process chamber 100 is maintained from about 3 Torr to about 50 Torr, such as about 20 Torr to about 40 Torr. A carrier gas may also be supplied to the chamber during operation 204. The ratio of the carrier gas to the process gas is about 1:1 to about 1:10. The carrier gas may include Argon (Ar), helium (He), or nitrogen (N₂). The flow rate of the process gas is about 100 sccm to 2000 sccm, such as 500 sccm to 1500 sccm. The flow rate of the carrier gas is about 2000 sccm to about 6000 sccm, such as about 3000 sccm to about 5000 sccm. During operation 206, the power supplied to the process chamber 100 is a high frequency (HF) power. The HF power increases the amount of inert termination groups on the top surface of the structures 302. The HF power is from about 500 W to about 3000 W, such as about 1000 W to about 2500 W, such as about 1500 W to about 2000 W.

At operation 208, as shown in FIG. 3C, a dielectric film 306 is deposited over the surface of the substrate 126. In some embodiments, the dielectric film 306 is a carbon gapfill. The dielectric film 306 is deposited subsequent to modifying a top surface of the structures 302. A precursor gas is supplied to the process chamber 100 to form the dielectric film 306. The precursor film may include CO₂, C₂H₂, C₃H₆, CH₄, C₆H₆, other carbon-containing gases, or combinations thereof.

The dielectric film 306 is deposited in a trench between adjacent structures. The inert termination group 304 enables differentiation between the top surface of the structure 302 from the trench 303 by disabling the carbon gapfill nucleation sites on the top surface of the structure 302, and partially disabling the in-trench carbon nucleation sites within the trenches 303. The disabling of the nucleation sites top surface of the structures 302, and the partially disabling of the in-trench carbon gapfill nucleation sites, enables a higher surface energy over a larger surface area within the trenches 303, thus enabling a longer residence time of precursor species and easier carbon gapfill nucleation within the trenches 303. Further, the inert termination group 304 enables a self-saturating growth of the carbon gapfill due to the disabling and partial disabling of the carbon nucleation sites. The deposition rate on the top surface of the structures 302 is 0 +/−100 Å/min. The dielectric film 306 growth on the top of the structures 302 is less than 1 Å. In some embodiments, the dielectric film 306 growth on the top of the structures 302 is 0 Å. The deposition species (e.g., C₂H₂⁺) to etching species (e.g., H₃⁺) ratio is between 0.1 to 5.

During operation 206, the process chamber 100 is maintained from about 10 Torr to about 50 Torr, such as about 20 Torr to about 40 Torr. In some embodiments, pressure during operation 206 is greater than the pressure during operation 204. The increase in pressure minimizes the damage to the structures 302. For example, the pressure during 204 may be 20% to about 40% greater than the pressure in operation 204, such as about 25% to about 33%. The ratio of the carrier gas to the process gas is about 1:1 to about 1:10. The carrier gas may include Argon (Ar), helium (He), or nitrogen (N₂). The flow rate of the precursor gas is about 100 to about 2000, such as about 100 to about 500. The flow rate of the process gas is about 100 sccm to about 2000 sccm, such as 500 sccm to 1500 sccm. The flow rate of the carrier has is about 2000 sccm to about 6000 sccm, such as about 3000 sccm to about 5000 sccm. During operation, the power supplied to the process chamber 100 is a high frequency (HF) power. The HF power is from about 500 W to about 3000 W, such as about 1000 W to about 2500 W, such as about 1500 W to about 2000 W.

The method 200 further enables self-planarizing and thus reduces the number of processes for increased throughput, while also resulting in high density carbon gapfill. Not to be bound by theory, but it is believed that a combination of pressure and H:C ratio provides a regime such that deposition is net positive in the CDs while net deposition is near zero on the wide pillar, thus enabling selective deposition of carbon films.

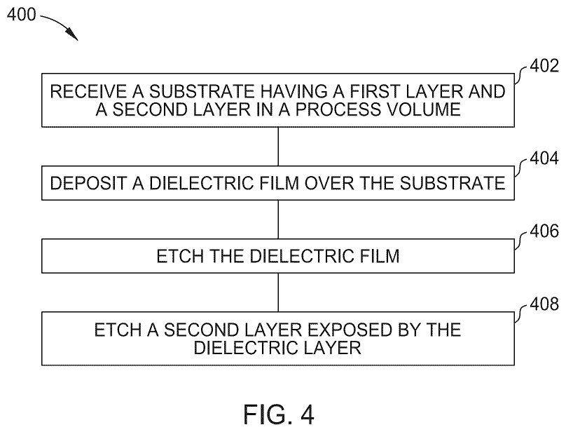

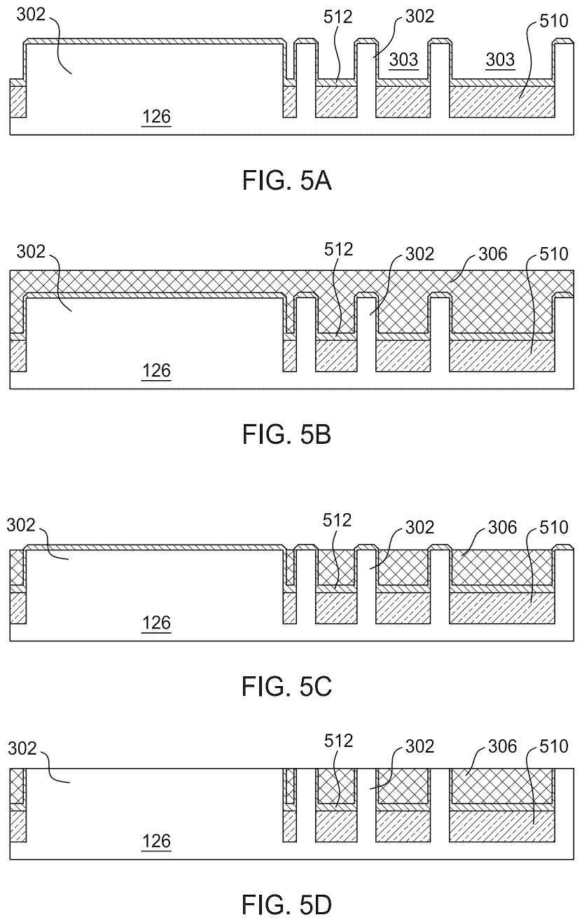

FIG. 4 is a diagram of a method 400 for forming a carbon gapfill via an etch back. FIGS. 5A-5D are schematic cross-sectional view of a substrate during the method 400. During the method 400, the substrate 126 is maintained at a temperature of about 300° C. to about 500° C., such as about 350° C. to about 450° C. During the method 400, the power supplied to the process chamber 100 is a high frequency (HF) power.

At operation 402, a substrate 126 is received in a process volume 146. The substrate 126, as shown in FIG. 5A, includes structures 302 disposed thereon. The structures 302 define a plurality of trenches 303 in between the structures 302. The structure 302 have varying critical dimensions, e.g., critical dimensions from about 8 nm to about 1000 nm, e.g., about 8 nm to about 800 nm, about 100 nm to about 600 nm, about 200 nm to about 400 nm, or about 250 nm to about 350 nm, about 8 nm to about 50 nm, about 50 nm to about 100 nm, about 100 nm to about 150 nm, about 150 nm to about 200 nm, about 200 nm to about 250 nm, about 250 nm to about 500 nm, or about 500 nm to about 1000 nm. In some embodiments, the structure 302 is a wide structure, e.g., has a CD of 500 nm to 40 μm. For example, a first critical dimension D1 may be from 3 nm to about 100 nm, while a second critical dimension D2 is from about 150nm to 400 nm. In some embodiments, the substrate 126 includes a first layer 510 and a second layer 512. The first layer 510 is a silicon oxide. The second layer 512 is a silicon nitride.

At operation 404, as shown in FIG. 5B, a dielectric film 306 is deposited over the substrate 126. The dielectric film 306 is deposited over the top surfaces of the structures and in the trenches 303. In some embodiments, the dielectric film 306 is a carbon gapfill. A precursor gas is supplied to the process chamber 100 to form the dielectric film 306. The precursor film may include CO₂, C₂H₂, C₃H₆, CH₄, C₆H₆, other carbon-containing gases, or a combination thereof.

During operation 404, the process chamber 100 is maintained from about 10 Torr to about 50 Torr, such as about 20 Torr to about 40 Torr. The carrier gas may include Argon (Ar), helium (He), hydrogen (H₂), or nitrogen (N₂). The flow rate of the precursor gas is about 100 to about 2000, such as about 100 to about 500. The flow rate of the carrier has is about 2000 sccm to about 6000 sccm, such as about 3000 sccm to about 5000 sccm. During operation, the power supplied to the process chamber 100 is a high frequency (HF) power. The HF power is from about 500 W to about 3000 W, such as about 1000 W to about 2500 W, such as about 1500 W to about 2000 W. The ratio of the carrier gas to the precursor gas is about 20:1 to about 1:1. Increasing the ratio of the carrier gas to the precursor gas enables an increase in etching and increases the radical flux.

At operation 406, as shown in FIG. 5C, the dielectric film 306 is etched. In one embodiment, a N₂+H₂ etch is performed at less than 1 Torr with a N₂ flow rate of about 0 sccm to about 5000 sccm and a H₂ flow rate of about 100 sccm to about 5000 sccm. In another embodiment, a Ar+H₂ etch is performed at less than 1 Torr with a Ar flow rate of about 0 sccm to about 5000 sccm and a H₂ flow rate of about 100 sccm to about 5000 sccm. In yet another embodiment, a N₂O+CO₂ etch is performed at less than 1 Torr with a N₂O and CO₂ flow rate of about 100 sccm to about 5000 sccm. The dielectric film 306 is etched such that the second layer 512 disposed on the top surfaces of the structures 302 is exposed.

At operation 408, as shown in FIG. 5D, the second layer 512 is etched. The second layer 512 is etched using hot phosphorous etching, which utilizes H₃PO₄. The second layer 512 is etched such that the second layer 512 is removed from the top surfaces of the structures 302.

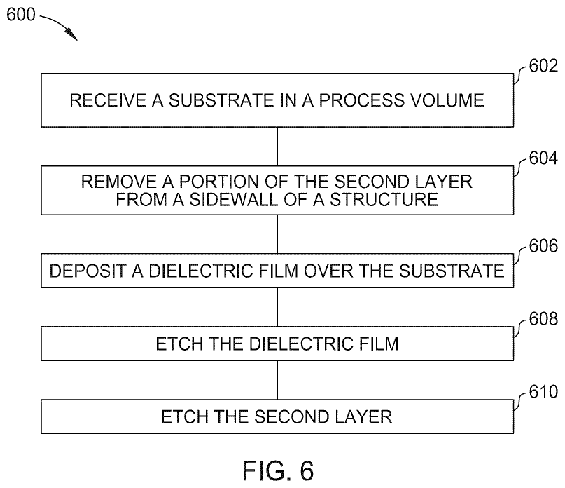

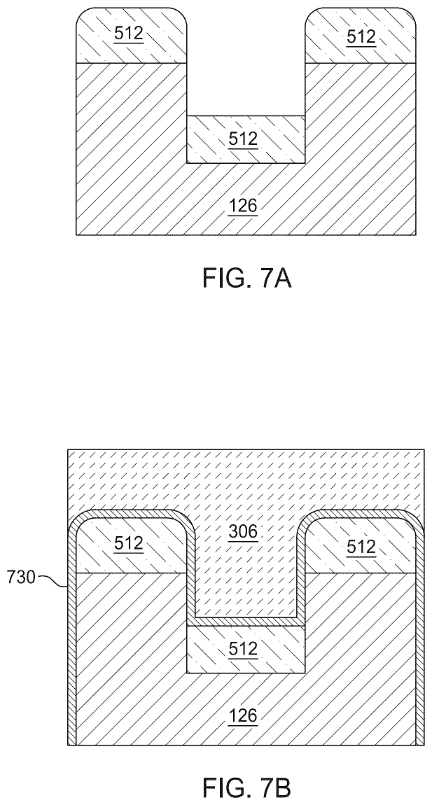

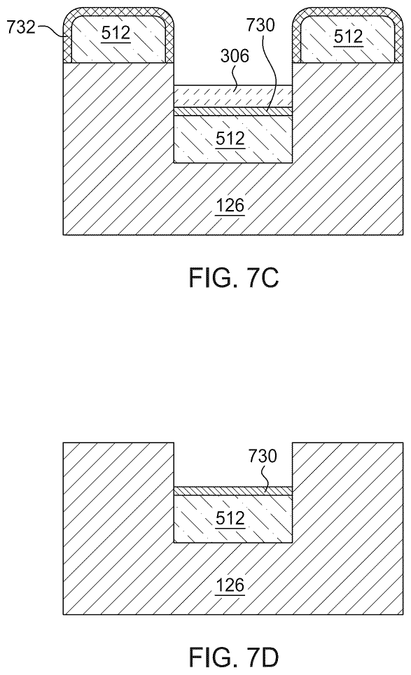

FIG. 6 is a flow diagram of a method 600. FIGS. 7A-7D are schematic cross-sectional views of a substrate during the method 600. During the method 600, the substrate 126 is maintained at a temperature of about 300° C. to about 500° C., such as about 350° C. to about 450° C. During the method 400, the power supplied to the process chamber 100 is a high frequency (HF) power.

At operation 602, a substrate 126 is received in a process volume 146. The substrate 126 includes structures 302 disposed thereon. The structures 302 define a plurality of trenches 303 in between the structures 302. The structure 302 have varying critical dimensions, e.g., critical dimensions from about 8 nm to about 1000 nm, e.g., about 8 nm to about 800 nm, about 100 nm to about 600 nm, about 200 nm to about 400 nm, or about 250 nm to about 350 nm, about 8 nm to about 50 nm, about 50 nm to about 100 nm, about 100 nm to about 150 nm, about 150 nm to about 200 nm, about 200 nm to about 250 nm, about 250 nm to about 500 nm, or about 500 nm to about 1000 nm. In some embodiments, the structure 302 is a wide structure, e.g., has a CD of 500 nm to 40 μm. For example, a first critical dimension D1 may be from 3 nm to about 100 nm, while a second critical dimension D2 is from about 150 nm to 400 nm. In some embodiments, the substrate 126 includes a first layer and a second layer 512. The first layer is a silicon oxide. The second layer 512 is a silicon nitride.

At operation 604, as shown in FIG. 7A, a portion of the second layer 512 deposited on the sidewall of the structure 302 is removed.

At operation 606, as shown in FIG. 7B, a dielectric film 306 is deposited over the substrate 126. In some embodiments, a first inert termination group 730 is formed over the second layer 512 using Si—H termination. The Si-H termination prevents the hot phosphorous etching. The Si—H termination is performed using argon and hydrogen treatments. The dielectric film 306 is deposited over the top surfaces of the structures and in the trenches 303. In some embodiments, the dielectric film 306 is a carbon gapfill. A precursor gas is supplied to the process chamber 100 to form the dielectric film 306. The precursor film may include CO₂, C₂H₂, C₃H₆, CH₄, C₆H₆, other carbon-containing gases, or a combination thereof.

During operation 606, the process chamber 100 is maintained from about 10 Torr to about 50 Torr, such as about 20 Torr to about 40 Torr. The carrier gas may include Argon (Ar), helium (He), hydrogen (H₂), or nitrogen (N₂). The flow rate of the precursor gas is about 100 to about 2000, such as about 100 to about 500. The flow rate of the carrier has is about 2000 sccm to about 6000 sccm, such as about 3000 sccm to about 5000 sccm. During operation, the power supplied to the process chamber 100 is a high frequency (HF) power. The HF power is from about 500 W to about 3000 W, such as about 1000 W to about 2500 W, such as about 1500 W to about 2000 W. The ratio of the carrier gas to the precursor gas is about 20:1 to about 1:1. Increasing the ratio of the carrier gas to the precursor gas enables an increase in etching and increases the radical flux.

At operation 608, as shown in FIG. 5C, the dielectric film 306 is etched. In one embodiment, a N₂+H₂ etch is performed at less than 1 Torr with a N₂ flow rate of about 0 sccm to about 5000 sccm and a H₂ flow rate of about 100 sccm to about 5000 sccm. In another embodiment, a Ar+H₂ etch is performed at less than 1 Torr with a Ar flow rate of about 0 sccm to about 5000 sccm and a H₂ flow rate of about 100 sccm to about 5000 sccm. In yet another embodiment, a N₂O+CO₂ etch is performed at less than 1 Torr with a N₂O and CO₂ flow rate of about 100 sccm to about 5000 sccm. The dielectric film 306 is etched such that the second layer 512 disposed on the top surfaces of the structures 302 is exposed. In embodiments, where N₂+H₂ etch is performed, a second inert termination group 732 is formed over the second layer 512.

At operation 610, as shown in FIG. 5D, the second layer 512 is etched. The second layer 512 is etched using hot phosphorous etching, which utilizes H₃PO₄. The second layer 512 is etched such that the second layer 512 is removed from the top surfaces of the structures 302.

While the foregoing is directed to embodiments of the present disclosure, other and further embodiments of the disclosure may be devised without departing from the basic scope thereof, and the scope thereof is determined by the claims that follow.

What is claimed is:

1. A method for depositing a dielectric film, comprising:
receiving a substrate in a process volume, the substrate comprising structures thereon having varying critical dimensions;
forming a plasma in the process volume;
chemically modifying a top surface of the structures with an inert termination group using the plasma; and
depositing, subsequent to modifying the top surface of the structures, the dielectric film over a surface of the substrate, wherein the dielectric film is deposited in a trench between adjacent structures.

2. The method of claim 1, further comprising a process gas being supplied to the process volume, wherein the plasma is formed from the process gas, the process gas comprising H₂, NH₃, N₂O, CO₂.

3. The method of claim 2, further comprising a precursor gas being supplied to the process volume, wherein a dielectric film is formed from the precursor gas, the precursor gas comprising C₂H₂, C₃H₆, CH₄, C₆H₆.

4. The method of claim 3, further comprising a carrier gas being supplied to the process volume, the carrier gas comprising argon (Ar), helium (He), hydrogen (H₂), or nitrogen (N₂).

5. The method of claim 4, wherein a ratio of the carrier gas to the process gas is about 1:1 to about 1:10.

6. The method of claim 5, wherein:
a flow rate of the precursor gas is about 100 sccm to about 500 sccm; and
a flow rate of the carrier gas is about 3000 sccm to about 5000 sccm.

7. The method of claim 1, wherein the substrate is maintained at a temperature of about 350° C. to about 450° C.

8. The method of claim 1, wherein a deposition rate on a top surface of the structures is 0+/−100 Å/min.

9. The method of claim 1, wherein the process volume is maintained from about 20 Torr to about 40 Torr.

10. A method for depositing a dielectric film, comprising:
receiving a substrate in a process volume, the substrate comprising structures thereon having varying critical dimensions and defining a plurality of trenches, wherein a first layer is disposed over the substrate in the trenches, and a second layer is disposed over the first layer in the trenches and over a top surface of the structures;
depositing a dielectric film over the substrate;
etching the dielectric film to expose the second layer disposed over the top surface of the structures; and
etching the second layer exposed by the dielectric film to remove the second layer from the top surface of the structures.

11. The method of claim 10, wherein the substrate 126 is maintained at a temperature of about 350° C. to about 450° C.

12. The method of claim 10, wherein the first layer is a silicon oxide and the second layer is a silicon nitride.

13. The method of claim 10, further comprising a precursor gas being supplied to the process volume, wherein a dielectric film is formed from the precursor gas, the precursor gas comprising C₂H₂, C₃H₆, CH₄, C₆H₆.

14. The method of claim 13, further comprising a carrier gas being supplied to the process volume, the carrier gas comprising argon (Ar), helium (He), hydrogen (H₂), or nitrogen (N₂).

15. The method of claim 14, wherein:
a flow rate of the precursor gas is about 100 sccm to about 500 sccm; and
a flow rate of the carrier gas is about 3000 sccm to about 5000 sccm.

16. The method of claim 15, ratio of the carrier gas to the precursor gas is about 1:1 to about 1:10.

17. The method of claim 10, wherein the process volume is maintained from about 20 Torr to about 40 Torr.

18. The method of claim 10, wherein a power during the deposition of the dielectric film is from about 1500 W to about 2000 W.

19. A device, comprising:
a substrate, comprising a plurality of structure, wherein the plurality of structures define a plurality of trenches; and
a dielectric film disposed in the trenches, the dielectric film comprising a carbon-containing material.

20. The device of claim 19, wherein an inert termination group is disposed on a top surface of the structures.
